(19) United States
(12) Patent Application Publication
(10) Pub. No.: US 2026/0371498 A1
(43) Pub. Date: Nov. 19, 2026

(54) Connection of Components

(71) Applicant: NanoWired GmbH, Gernsheim (DE)

(72) Inventors: Olav Birlem, Gernsheim (DE); Sebastian Quednau, Gernsheim (DE); Florian Weissenborn, Gernsheim (DE)

(21) Appl. No.: 19/130,156

(22) PCT Filed: Nov. 16, 2023
(86) PCT No.: PCT/EP2023/082016

§ 371 Date: May 15, 2025

(30) Foreign Application Priority Data
Dec. 7, 2022 (DE) 10 2022 132 447.8

(51) Int. Cl. H05K 3/30; H05K 1/18

(52) U.S. Cl. CPC H05K 3/301; H05K 1/18

(57) ABSTRACT

Method for connecting a first component to a second component, comprising:
a) providing the first component and the second component,
b) bringing the first component and the second component together,
c) heating,
wherein by means of steps b) and c) a secondary region of the surface of the first component and a secondary region of the surface of the second component are connected together by way of a connecting substance, and contact regions of the surface of the first component and contact regions of the surface of the second component are connected together in pairs by way of a respective plurality of nanowires.

The invention relates to a method for connecting two components and to a corresponding arrangement of two components connected together. The invention can be used in particular in the technical field of electronics in order to connect electronic components together in an electrically and/or thermally conducting manner.

For the connection of two components, in particular in the technical field of electronics, so-called hybrid bonding is known. In this method, contacts, for example of copper, are applied to the two components to be connected, and gaps between the contacts are filled with an adhesive. If the two components are brought together, the contacts of the components come into contact with one another in pairs. The components are connected together by way of the adhesive. A mechanically stable bond by which the components are fixed is thus already formed. Annealing is then carried out. In the annealing, the components are heated so that the contacts of the components are also connected together.

Hybrid bonding has the disadvantage that, during the annealing, the components are subjected to a comparatively high temperature for a comparatively long time. Temperature-sensitive components such as semiconductor chips can thus be damaged. In addition, annealing requires the surfaces of the contacts to be particularly clean. A dust particle between two contacts can prevent the two contacts being connected together in the desired manner by the annealing. Hybrid bonding is therefore generally carried out under strict cleanroom conditions. In particular, it is in most cases avoided that the components are transported from one cleanroom into a different cleanroom at a different location between the contacts being applied and the contacts being brought together.

In addition, the fusion bonding that is generally carried out within the context of hybrid bonding, for example, requires a particularly smooth surface of the components to be connected together. To this end, in addition to cleanroom conditions, additional polishing steps, for example in the form of chemical mechanical polishing (CMP), are often also necessary. These steps are complex and expensive. Above all, cleaning of the surfaces after polishing, which is required in most cases, is also expensive. Generally, the outlay for hybrid bonding is thus comparatively high.

As an alternative to hybrid bonding, numerous other methods for connecting components together in particular in the technical field of electronics are known. However, compared to hybrid bonding, these methods in particular have the disadvantage that the contact faces of the components that are to be connected together must be comparatively large and/or arranged at a comparatively large distance from one another. A comparatively large pitch is thus required. This is the case in wire bonding, for example. Such methods are generally less precise than hybrid bonding.

Outside the technical field of electronics, there are also applications in which two components are to be connected together and in which the known methods have similar disadvantages. This is the case, for example, for precision mechanical components.

The object of the present invention is to precisely and gently connect two components together in a simple manner. An arrangement of components correspondingly connected together is additionally to be provided.

These objects are achieved by the method and the arrangement according to the independent claims. Further advantageous embodiments are indicated in the dependent claims. The features set out in the claims and in the description can be combined with one another in any desired, technologically expedient manner.

According to the invention, a method for connecting a first component to a second component is provided. The first component and the second component each have a surface having a plurality of electrically conducting contact regions which are arranged spaced apart from one another and are electrically insulated from one another. The method comprises:
a) providing the first component, wherein on the surface of the first component, in the contact regions, there is a respective plurality of electrically conducting nanowires, and providing the second component, wherein on the surface of the second component, outside the contact regions, in a secondary region, there is a connecting substance, wherein the connecting substance is suitable for connecting the components together by way of the connecting substance,
b) bringing the first component and the second component together, so that
   the nanowires in the contact regions of the surface of the first component each come into contact with one of the contact regions of the surface of the second component, and
   a connection to a secondary region of the surface of the first component is formed by the connecting substance on the second component, wherein the secondary region of the surface of the first component is arranged outside the contact regions of the surface of the first component,
c) heating at least the nanowires and the contact regions of the surface of the second component to a temperature of at least 90 °C,
and/or
acting at least upon the nanowires and the contact regions of the surface of the second component by means of plasma activation,
   wherein by means of steps b) and c) the contact regions of the surface of the first component and the contact regions of the surface of the second component are connected together in pairs by way of a respective plurality of nanowires.

By means of the method, two components can be connected together. The components are preferably electronic components. For example, a printed circuit board as a first component can be connected to a semiconductor chip as a second component, or vice versa. However, the invention relates only to the connection between the components. The advantages of the method that are described herein can therefore be achieved irrespective of the nature of the components. Thus, it is immaterial whether the components fall under the definition of electronic components or not. Provided that two components are to be connected together in a technical field outside electronics, the described method can also be used therefor.

By means of the method, the components can be connected together in particular mechanically. On completion of the method, the components thus hold firmly together. In addition, multiple electrically conducting connections between the components are obtained by means of the method. These connections are independent of one another, that is to say electrically separated from one another. Thus, for example, a computer chip having multiple pins as the first component can be attached by way of a corresponding number of electrically conducting connections to a printed circuit board having a corresponding number of contacts as the second component, or vice versa. The components can additionally be connected together in a thermally conducting manner by means of the method. In particular, the electrically conducting connections can also be thermally conducting.

Electrical and/or thermal conductivity in the meaning used here is present in particular in the case of metals such as, for example, copper, which are generally referred to as “electrically conductive” or, synonymously, as “electrically conducting”, or “thermally conductive” or “thermally conducting”. In particular, materials which are considered to be electrically or thermally insulating are generally not to be regarded here as being electrically or thermally conductive.

The first component and the second component each have a surface having a plurality of electrically conducting contact regions which are arranged spaced apart from one another and are electrically insulated from one another. The first component thus has a surface having a plurality of electrically conducting contact regions, wherein the electrically conducting contact regions of the surface of the first component are arranged spaced apart from one another and are electrically insulated from one another. The second component has a surface having a plurality of electrically conducting contact regions, wherein the electrically conducting contact regions of the surface of the second component are arranged spaced apart from one another and are electrically insulated from one another.

By means of the described method, the contact regions of the surface of the first component and the contact regions of the surface of the second component can be connected together in an electrically conducting manner in pairs. That the contact regions are connected together in pairs means that a first contact region of the surface of the first component is connected to a first contact region of the surface of the second component, that a second contact region of the surface of the first component is connected to a second contact region of the surface of the second component, and so on. Generally, an n^{th} contact region of the surface of the first component is thus connected to an n^{th} contact region of the surface of the second component, which applies for all n between 1 and the total number of contact regions per component. Each contact face of the first component is thus associated with precisely one of the contact faces of the second component, and vice versa. That the contact regions are connected together in pairs implies that, for the method, the same number of contact regions is used on both components. It also implies that the contact regions of the two components are positioned and dimensioned corresponding to one another.

In step a) of the method, the first component and the second component are provided. On the surface of the first component so provided, in the contact regions, there is a respective plurality of electrically conducting nanowires. On the surface of the second component provided in step a), outside the contact regions, in a secondary region, there is a connecting substance. On completion of step a), the first component and the second component are thus available in the described form for the further method.

The term secondary region has been chosen in order to differentiate it linguistically from the contact regions. The secondary region can be regarded as being subordinate to the contact regions inasmuch as only the contact regions serve for the electrical contacting of the components. Alternatively, the contact region could also be referred to neutrally as a region of a first type, or the contact regions could be referred to as regions of a first type and the secondary region as a region of a second type, or the secondary regions could be referred to as regions of a second type.

A nanowire is here understood as being any material body which has a wire-like form and a size in the range of from a few nanometres to a few micrometres. A nanowire can have, for example, a circular, oval or polygonal base area. In particular, a nanowire can have a hexagonal base area. Preferably, the nanowires have a length in the range of from 100 nm [nanometres] to 100 μm [micrometres], in particular in the range of from 500 nm to 30 μm. Furthermore, the nanowires preferably have a diameter in the range of from 10 nm to 10 μm, in particular in the range of from 30 nm to 2 μm. The term diameter here relates to a circular base area, wherein in the case of a base area other than a circular base area a comparable definition of a diameter is to be used. It is particularly preferred that all the nanowires used have the same length and the same diameter.

That the first component is provided in step a) can be achieved in that the first component is configured in the described manner before the start of the method. In that case, the nanowires are arranged on the surface of the first component in the contact regions of the surface of the first component even before the start of the method. This is possible, for example, in that a correspondingly prepared component is acquired from a supplier. Alternatively, the first component can, however, also be configured in the described manner as part of the method. In that case, the plurality of nanowires can be provided on the surface of the first component in the contact regions of the surface of the first component in step a). This is possible by galvanic growth, for example.

That the second component is provided in step a) can be achieved in that the second component is configured in the described manner before the start of the method. In that case, the connecting substance is arranged on the surface of the second component in the secondary region of the surface of the second component even before the start of the method. This is possible, for example, in that a correspondingly prepared component is acquired from a supplier. Alternatively, the second component can, however, also be configured in the described manner as part of the method. In that case, the connecting substance can be provided on the surface of the second component in the secondary region of the surface of the second component in step a).

The connecting substance is suitable for connecting the components together by way of the connecting substance. For example, the connecting substance can be an adhesive, in particular a PI adhesive. However, the described method is not limited to the use of an adhesive. The components can also be connected together with other substances which do not fall under the definition of an adhesive. For example, the connecting substance can be an oxide such as silicon oxide. If the surface in the secondary region is formed of an oxide, the oxide used as the connecting substance can be connected to the surface by fusion bonding. It is therefore preferred that the connecting substance is an oxide, that the surface of the first component in the secondary region is formed of an oxide and/or that the surface of the second component in the secondary region is formed of an oxide.

It is sufficient that the components initially hold together weakly by way of the connecting substance. This can be construed as being a preliminary connection. In the case of an oxide such as silicon oxide, such a connection can be formed even before the fusion bonding. In the further course of the method, the connection obtained with the connecting substance can be strengthened further. This can take place in particular in the case of an oxide such as silicon oxide as the connecting substance by the fusion bonding.

It is sufficient that the connecting substance is arranged in the case of the second component provided in step a) in the secondary region. After step a), there is preferably no connecting substance on the first component that falls under the definition of the term connecting substance used herein. This simplifies the method inasmuch as the connecting substance does not also have to be applied to the first component. The connecting substance then comes into contact with the first component only in step b). Alternatively, however, the connecting substance can be arranged in the corresponding secondary region both in the case of the first component provided in step a) and in the case of the second component provided in step a). In step b), the connecting substance on the second component then comes into contact with the connecting substance on the first component.

The first component provided in step a) has multiple contact regions, and the second component provided in step a) has multiple contact regions and a secondary region. At the latest in the course of the method, a secondary region is also formed on the surface of the first component. It is sufficient that the first component and the second component each have exactly one secondary region. In that case, the secondary region of the first component and the secondary region of the second component form a pair. This case will be discussed below. It is, however, also possible that the first component and the second component each have multiple secondary regions which are separated from one another. In that case, there are multiple pairs each consisting of a secondary region of the first component and a secondary region of the second component. In this case, what has been said herein for the exactly one pair of secondary regions applies correspondingly.

In step b), the two components are brought together. Firstly, the nanowires in the contact regions of the surface of the first component each come into contact with one of the contact regions of the surface of the second component. At the latest at the end of the method, the contact regions of the surface of the first component and the contact regions of the surface of the second component are connected together in pairs by way of a respective plurality of nanowires. Thus, at the latest at the end of the method, a first contact region of the surface of the first component is connected by way of a first plurality of nanowires to a first contact region of the surface of the second component, a second contact region of the surface of the first component is connected by way of a second plurality of nanowires to a second contact region of the surface of the second component, and so on. In general, at the latest at the end of the method, an n^{th} contact region of the surface of the first component is connected by way of an n^{th} plurality of nanowires to an n^{th} contact region of the surface of the second component, which applies for all n between 1 and the total number of contact regions per component.

The nanowires each have two ends. Preferably at the latest at the end of step a), a first end of the nanowires is fixedly connected in the corresponding contact region of the surface of the first component to the surface of the first component. By means of step b), a second end of the nanowires comes into contact in the corresponding contact region of the surface of the second component with the surface of the second component. Preferably, the first end of the nanowires is perpendicular to the surface of the first component and/or the second end of the nanowires is perpendicular to the surface of the second component. However, it is not important that the nanowires are arranged precisely as described in this paragraph. In particular, it is not a problem for the described method if nanowires—as is often the case in practice—have grown unevenly and are not all oriented in the same way.

The nanowires on the first component are arranged in the contact regions of the surface of the first component. The nanowires are already connected to the surface of the first component at the latest at the end of step a). This can be achieved, for example, in that the nanowires are grown onto the surface of the first component by galvanic growth in the contact regions of the surface of the first component in step a) or before the start of the method. However, it is also conceivable that the nanowires are first produced separately in step a) or before the start of the method, for example by galvanic growth, and are then transferred to the surface of the first component, so that the nanowires are connected in the contact regions of the surface of the first component to the surface of the first component. The nanowires are preferably formed of the same material as the surface of the first component in the contact regions. The nanowires are thus able to adhere particularly well to the surface of the first component. Preferably, the nanowires and the surface of the first component in the contact regions are each formed of a metal, in particular of copper. The contact regions of the surface of the first component are in particular defined in that the nanowires are arranged in those regions at the latest at the end of step a). However, that the contact regions of the surface of the first component are arranged spaced apart from one another and are electrically insulated from one another additionally implies that the surface of the first component between the contact regions is formed of a different, electrically insulating material. In this respect, the contact regions of the surface of the first component can be recognized as such even before the nanowires have grown.

After step b), the nanowires are in contact with the surface of the second component in the contact regions of the surface of the second component. This may be loose contact. This means that, although the nanowires touch the surface of the second component, they are not yet fixedly connected thereto. In this case, such a fixed connection is only produced in the further course of the method. However, it is possible that the nanowires are already connected to the surface of the second component at the end of step b). In that case, this connection is strengthened in the further course of the method.

The contact regions of the surface of the second component are in particular defined in that the nanowires are in contact in that region with the surface of the second component at the latest at the end of step b). However, that the contact regions of the surface of the second component are arranged spaced apart from one another and are electrically insulated from one another additionally implies that the surface of the second component between the contact regions is formed of a different, electrically insulating material. In this respect, the contact regions of the surface of the second component can be recognized as such even before the nanowires come into contact with the surface of the second component in step b).

The nanowires are preferably formed of the same material as the surface of the second component in the contact regions. The nanowires are thus able to adhere particularly well to the surface of the second component. Preferably, the nanowires and the surface of the second component in the contact regions are each formed of a metal, in particular of copper.

Secondly, a connection of the secondary region of the surface of the first component to a secondary region of the surface of the second component is formed by means of the connecting substance on the second component. Where the connecting substance is an adhesive, this connection is an adhesive connection. Where the connecting substance is an oxide such as silicon oxide and the corresponding surface in the secondary region is formed of an oxide, this connection is an oxide bond.

If the connecting substance is arranged in the secondary region only in the case of the second component provided in step a), but not on the first component provided in step a), the connection is formed only with this connecting substance.

The connecting substance on the second component is arranged in the secondary region of the surface of the second component. The connecting substance is already connected to the surface of the second component at the latest at the end of step a). This can be achieved, for example, in that the connecting substance is applied to the surface of the second component in the secondary region of the surface of the second component in step a) or before the start of the method. The secondary region of the surface of the second component is defined in that the connecting substance is arranged in that region at the latest at the end of step a). In addition, the secondary region of the surface of the second component does not have to be recognizable as a separate region. That is possible, however, for example in that the surface of the second component is formed of a different material in the secondary region than outside the secondary region. In particular, the secondary region can be formed by the part of the surface of the second component that does not belong to any of the contact regions of the second component. The contact regions can be electrically insulated from one another in that the surface of the second component is electrically insulating in the secondary region.

At the latest after step b), the connecting substance is in contact with the surface of the first component in the secondary region of the surface of the first component. In this respect, the two components can be connected together by way of the connecting substance.

If the connecting substance is an adhesive, the adhesive can cure at any desired time after step b). That the adhesive is not already cured when the two components are brought together in step b) naturally follows from the fact that an adhesive connection is formed.

The secondary region of the surface of the first component is defined in that the connecting substance is in contact in that region with the surface of the first component at the latest at the end of step b). In addition, the secondary region of the surface of the first component does not have to be recognizable as a separate region. In particular, the secondary region of the surface of the first component does not have to be recognizable as such even before step b). It is sufficient that the secondary region of the surface of the first component is formed in that the connecting substance comes into contact in step b) with that part of the surface of the first component. However, it is also possible that the secondary region of the surface of the first component is recognizable as a separate region even before step b), for example in that the surface of the first component is formed of a different material in the secondary region than outside the secondary region. In particular, the secondary region can be formed by the part of the surface of the first component that does not belong to any of the contact regions of the first component. The contact regions can be electrically insulated from one another in that the surface of the first component is electrically insulating in the secondary region.

If the connecting substance is arranged in the corresponding secondary region both in the case of the first component provided in step a) and in the case of the second component provided in step a), a mechanical connection to a secondary region of the surface of the first component is formed by the connecting substance on the second component inasmuch as the connecting substance on the second component is involved in the formation of this connection. In addition, the connecting substance on the first component is also involved in the formation of this connection.

By means of the described method, the two components can be connected together in two ways at the same time. Firstly, a connection between the components can be obtained by way of the connecting substance. In the case of an adhesive as the connecting substance, it is sufficient for this purpose that the adhesive cures after step b). Secondly, multiple nanowire connections between the components can be obtained by way of the nanowires. The nanowire connections are obtained at the latest by step c). The connection formed with the connecting substance in particular serves the purpose of fixedly connecting the two components together, so that the two components no longer move relative to one another before the nanowire connections are finally formed. In this respect, the connection is an auxiliary means which is used during the method. However, this connection additionally also serves the purpose of permanently mechanically connecting the two components together. In this respect, this connection also has a purpose once the method is complete. In addition to the connection formed by the connecting substance, the two components are also mechanically connected together by the nanowire connections.

In step c), at least the nanowires and the contact regions of the surface of the second component are heated to a temperature of at least 90 °C, in particular of at least 170 °C, and/or at least the nanowires and the contact regions of the surface of the second component are acted upon by means of plasma activation. The “and” case is preferred. In that case, heating can result from the plasma activation and/or can be achieved by an additional heating measure.

As a result of the heating and/or the action by means of plasma activation, the nanowires—unless this is already the case—are connected to the surface of the second component. It has been described hereinbefore that there may be only loose contact between the nanowires and the surface of the second component after step b), and that this contact can be strengthened in the further course of the method. This strengthening can be achieved with step c). As a result of the heating and/or the action by means of plasma activation, the nanowires and the surface of the second component can be connected together on an atomic level. The connection can further be strengthened if the components are temporarily pressed together.

At the latest by means of step c), nanowire connections between the first component and the second component form between the contact regions. These nanowire connections are particularly strong if the surface of the first component in the contact regions, the nanowires and the surface of the second component in the contact regions are formed of the same material. This is accordingly preferred. Particularly preferably, this material is a metal, in particular copper.

In order to connect the nanowires to the surface of the second component, it is sufficient that in step c) the nanowires and the contact regions of the surface of the second component are heated. However, it is not important for the formation of this connection whether further parts of the two components are also heated. Step c) is carried out in the simplest manner by heating the first component and the second component as a whole, for example by placing the two components together in an oven. For action by means of plasma activation in step c), it is sufficient that the nanowires and the contact regions of the surface of the second component are acted upon by the plasma activation. However, it is not important for the formation of this connection whether further parts of the two components are also subjected to the plasma activation. Step c) can therefore also be carried out in a simple manner by subjecting the first component and the second component as a whole to the plasma activation. The plasma employed for the plasma activation can be used to activate both the nanowires and, for example, an oxide of the contact faces. With the latter, oxide-oxide bonds can be formed.

A comparatively low temperature is sufficient for the heating in step c). Even at only 90 °C, satisfactory results can be achieved. In particular, heating to a temperature that is substantially lower than the temperatures usually required for hybrid bonding is sufficient for the described method. Moreover, it is sufficient that the heating in step c) is carried out for a short time. In particular, heating over a period of time that is substantially shorter than the periods of time usually required for hybrid bonding is sufficient for the described method.

By means of steps b) and c), the two components are connected together by way of the nanowires and the connecting substance. Steps b) and c) are thus carried out in particular such that, in addition to the connection formed with the connecting substance, multiple nanowire connections between the surface of the first component and the surface of the second component are formed.

Heating in step c) preferably takes place to a temperature of from 90 to 300 °C, in particular to 170 °C. The temperature of the two components is preferably below 300 °C, in particular below 200 °C, throughout the entire method.

Heating in step c) preferably takes place for a period of time of from 1 to 10 min, in particular of 2 min. Preferably, the temperature of the two components is above a value of 50 °C for not more than 10 min throughout the entire method.

The described method is advantageous, in particular compared to hybrid bonding, irrespective of the temperature actually chosen and the period of time for which heating is actually carried out. Generally, the nanowires connect to the surface of the second component better than, for example, solid metal contacts connect to one another in hybrid bonding. In order to heat a solid metal contact to a desired temperature, a greater heat input is required than in the case of a nanowire. This corresponds to a higher temperature and/or a longer period of time for heating. The described method is therefore particularly gentle in particular compared to hybrid bonding.

In addition, the described method is particularly simple in particular compared to hybrid bonding. It has been found that the cleanroom requirements in the case of the described method are lower and can more easily be maintained. This is due in particular to the use of the nanowires. While a dust particle, for example, in hybrid bonding can prevent contact between two contacts, this is the case in the described method only for the nanowires that are directly affected. The nanowires next to the dust particle can still form the connection.

In particular compared to methods which are used as an alternative to hybrid bonding, the described method is particularly precise. Known methods often allow only contacts that are comparatively large and/or comparatively far away from one another to be connected together. By contrast, in the described method, the contact regions can be particularly small and/or arranged particularly close together. This is possible due to the connecting substance, because the two components can be fixedly connected together therewith before the nanowire connections are formed.

In a preferred embodiment of the method, the contact regions of the surface of the first component are raised relative to the secondary region of the surface of the first component.

The nanowires can have a negligibly small length compared to the extent of the connecting substance. By raising the contact regions, the nanowires can nevertheless connect the surfaces of the two components together. In particular in the described embodiment, the surface of the second component can be flat.

The contact regions of the surface of the first component can be raised relative to the secondary region of the surface of the first component in that the contact regions of the surface are formed on a respective contact that is mounted on the remainder of the first component. The contact can be a metal pad, for example. In such a case, the metal pad is construed as being part of the first component. The surface of the first component is thus formed in the region of the metal pad by the surface of the metal pad.

There are numerous alternatives to the described embodiment. For example, it is conceivable that the secondary region of the second component is recessed and the surface of the first component is flat.

In a further preferred embodiment of the method, the surface of the second component provided in step a) is metallized with a metallization layer in the contact regions, wherein the metallization layer also extends at least partially over a lateral edge of the connecting substance on the second component.

The nanowires can be attached particularly well to a metal. This is the case in particular when the nanowires are likewise formed of a metal, especially when the nanowires and the metallization layer are formed of the same metal. By means of the metallization layer, electrical conductivity of the surface of the second component in the contact regions can be made possible.

As a further aspect of the invention there is provided an arrangement. The arrangement comprises a first component and a second component, wherein the first component and the second component each have a surface having a secondary region and a plurality of electrically conducting contact regions formed outside the secondary region, wherein the contact regions are in each case arranged spaced apart from one another and are electrically insulated from one another, and wherein the first component and the second component are connected together in that
the contact regions of the surface of the first component and the contact regions of the surface of the second component are connected together in pairs by way of a respective plurality of nanowires, and
the secondary region of the surface of the first component and the secondary region of the surface of the second component are connected together by way of a connecting substance.

The described advantages and features of the method are applicable and transferrable to the arrangement, and vice versa. The method is preferably adapted for the production of the arrangement. The arrangement is preferably produced by the method.

In a preferred embodiment of the arrangement, the contact regions of the surface of the first component each adjoin the secondary region of the surface of the first component, and/or the contact regions of the surface of the second component each adjoin the secondary region of the surface of the second component. The “and” case is preferred.

In this embodiment, the surfaces of the two components can each be used particularly efficiently.

The invention will be explained in greater detail hereinbelow with reference to the figures. The figures show a particularly preferred exemplary embodiment, but the invention is not limited thereto. The figures and the size ratios shown therein are only schematic. In the figures:

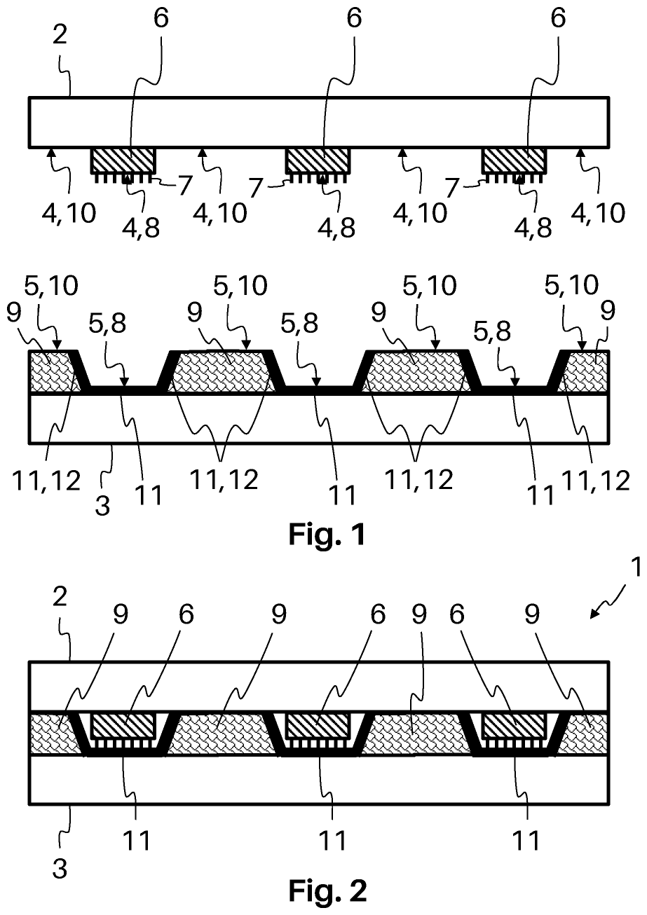

FIG. 1: shows a first component and a second component which can be connected together by a method according to the invention, so that an arrangement according to the invention is formed,

FIG. 2: shows the arrangement according to the invention, which can be obtained with the components of FIG. 1.

FIG. 1 shows a first component 2 and a second component 3. The two components 2, 3 are intended to be connected together.

In three contact regions 8 of a surface 4 of the first component 2 there is in each case a plurality of nanowires 7 on the surface 4 of the first component 2. In a secondary region 10 of a surface 5 of the second component 3 there is a connecting substance 9 on the surface 5 of the second component 3. Outside the plane of the drawing, the parts of the secondary region 10 of the surface 4 of the second component 3 that can be seen in FIG. 1 are connected together, so that a continuous secondary region 10 is formed. Between the contact regions 8 of the surface 4 of the first component 2, the surface 4 of the first component 2 has a secondary region 10. Outside the plane of the drawing, the parts of the secondary region 10 of the surface 4 of the first component 2 that can be seen in FIG. 1 are connected together, so that a continuous secondary region 10 is formed. In this secondary region, a connecting substance 9 on the second component 3 can be brought into contact with the surface 4 of the first component 2. Between the parts of the secondary region 10 of the surface 5 of the second component 3 that are visible, the surface 5 of the second component 3 has three contact regions 8. In these contact regions, the nanowires 7 on the first component 2 can be brought into contact with the surface 5 of the second component 3. The components 2, 3 can thus be connected together by way of the nanowires 7 and by way of the connecting substance 9.

The contact regions 8 of the surface 4 of the first component 2 are raised relative to the secondary region 10 of the surface 4 of the first component 2 by a protuberance 6.

In the case of the second component 3, the surface 5 in each of the contact regions 8 is metallized with a metallization layer 11. The metallization layer 11 also extends at least partially over a lateral edge 12 of the connecting substance 9 on the second component 3.

The surface 4 of the first component 2 is formed in the contact regions 8 of the surface 4 of the first component 2 of an electrically conducting material. The nanowires 7 are formed of an electrically conducting material. The surface 5 of the second component 3 is formed in the contact regions 8 of the surface 5 of the second component 3 of an electrically conducting material.

The two components 2 and 3 can be connected together by a method which comprises the following steps:
a) providing the components 2, 3 shown in FIG. 1,
b) bringing the first component 2 and the second component 3 together, so that
   the nanowires 7 in the contact regions 8 of the surface 4 of the first component 2 each come into contact with one of the contact regions 8 of the surface 5 of the second component 3, and
   by means of the connecting substance 9 on the second component 3, a connection to a secondary region 10 of the surface 4 of the first component 2 is formed, wherein the secondary region 10 of the surface 4 of the first component 2 is arranged outside the contact regions 8 of the surface 4 of the first component 2,
c) heating at least the nanowires 7 and the contact regions 8 of the surface 5 of the second component 3 to a temperature of at least 90 °C,
and/or
acting at least upon the nanowires 7 and the contact regions 8 of the surface 5 of the second component 3 by means of plasma activation,
   wherein by means of steps b) and c) the contact regions 8 of the surface 4 of the first component 2 and the contact regions 8 of the surface 5 of the second component 3 are connected together in pairs by way of a respective plurality of nanowires 7.

FIG. 2 shows an arrangement 1 which can be obtained by this method. The arrangement 1 comprises the first component 2 and the second component 3. The first component 2 and the second component 3 each have a surface 4, 5 having a secondary region 10 and a plurality of electrically conducting contact regions 8 formed outside the secondary region 10. The contact regions 10 are each arranged spaced apart from one another and are electrically insulated from one another. The first component 2 and the second component 3 are connected together in that
the contact regions 8 of the surface 4 of the first component 2 and the regions 8 of the surface 5 of the second component 3 are connected together in pairs by way of a 5 respective plurality of nanowires 7, and
the secondary region 10 of the surface 4 of the first component 2 and the secondary region 10 of the surface 5 of the second component 3 are connected together by way of a connecting substance 9.

The contact regions 8 of the surface 4 of the first component 2 each adjoin the secondary region 10 of the surface 4 of the first component 2, and the contact regions 8 of the surface 5 of the second component 3 each adjoin the secondary region 10 of the surface 5 of the second component 3.

### LIST OF REFERENCE SIGNS

1 Arrangement
2 First component
3 Second component
4 Surface of the first component
5 Surface of the component
6 Protuberance
7 Nanowires
8 Contact region
9 Connecting substance
10 Secondary region
11 Metallization
12 Lateral edge

1. Method for connecting a first component to a second component, wherein the first component and the second component each have a surface having a plurality of electrically conducting contact regions which are arranged spaced apart from one another and are electrically insulated from one another, and wherein the method comprises:
a) providing the first component, wherein on the surface of the first component, in the contact regions, there is a respective plurality of electrically conducting nanowires, and providing the second component, wherein on the surface of the second component, outside the contact regions, in a secondary region, there is a connecting substance, wherein the connecting substance is suitable for connecting the components together by way of the connecting substance,
b) bringing the first component and the second component together, so that
the nanowires in the contact regions of the surface of the first component each come into contact with one of the contact regions of the surface of the second component, and
a connection to a secondary region of the surface of the first component is formed by the connecting substance on the second component, wherein the secondary region of the surface of the first component is arranged outside the contact regions of the surface of the first component,
c) heating at least the nanowires and the contact regions of the surface of the second component to a temperature of at least 90 °C, and/or
acting at least upon the nanowires and the contact regions of the surface of the second component by means of plasma activation,
wherein by means of steps b) and c) the contact regions of the surface of the first component and the contact regions of the surface of the second component are connected together in pairs by way of a respective plurality of the nanowires.

2. Method according to claim 1, wherein the contact regions of the surface of the first component are raised relative to the secondary region of the surface of the first component.

3. Method according to claim 1, wherein, the surface of the second component provided in step a) is metallized with a metallization layer in the contact regions, wherein the metallization layer also extends at least partially over a lateral edge of the connecting substance on the second component.

4. Arrangement comprising a first component and a second component, wherein the first component and the second component each have a surface having a secondary region and a plurality of electrically conducting contact regions formed outside the secondary region, wherein the contact regions are in each case arranged spaced apart from one another and are electrically insulated from one another, and wherein the first component and the second component are connected together in that
the contact regions of the surface of the first component and the contact regions of the surface of the second component are connected together in pairs by way of a respective plurality of nanowires, and
the secondary region of the surface of the first component and the secondary region of the surface of the second component are connected together by way of a connecting substance.

5. Arrangement according to claim 4, wherein the contact regions of the surface of the first component each adjoin the secondary region of the surface of the first component, and/or the contact regions of the surface of the second component each adjoin the secondary region of the surface of the second component.

6. Method according to claim 2, wherein, the surface of the second component provided in step a) is metallized with a metallization layer in the contact regions, wherein the metallization layer also extends at least partially over a lateral edge of the connecting substance on the second component.
